(19) United States
(12) Patent Application Publication
(10) Pub. No.: US 2024/0302440 A1
(43) Pub. Date: Sep. 12, 2024

(54) DYNAMIC AND PREDICTIVE CONTROL OF BATTERY CHARGING

(71) Applicant: GM GLOBAL TECHNOLOGY OPERATIONS LLC, Detroit, MI (US)

(72) Inventors: Ibrahim Haskara, Macomb, MI (US); Bharatkumar Hegde, Bloomfield Hills, MI (US); Chen-fang Chang, Bloomfield Hills, MI (US)

(21) Appl. No.: 18/180,520

(22) Filed: Mar. 8, 2023

(51) Int. Cl. G01R 31/367; G01R 31/36; G01R 31/3842; G05B 13/04; H02J 7/00

(52) U.S. Cl. CPC G01R 31/367; G01R 31/3648; G01R 31/3842; G05B 13/048; H02J 7/007

(57) ABSTRACT

A system for control of a battery system includes a processor electrically connected to the battery system. The processor is configured to perform, in real time during a charging process, acquiring a set of charging parameter measurements, and estimating a dynamic performance variable in real time, the dynamic performance variable related to an electrochemical phenomenon occurring within the battery system during the charging process. The processor is also configured to perform, in real time during the charging process, determining a charging limit based on the dynamic performance variable and a model of the battery system, predicting a future state of the battery system, generating a target current profile based on the future state and the charging limit, the target current profile configured to maintain the dynamic performance variable within the charging limit, and controlling the current applied to the battery system based on the target current profile.

### INTRODUCTION

The subject disclosure relates to control of battery charging processes, and more specifically, to real time control of charging current and/or other charging parameters based on electrochemical phenomena.

Vehicles, including gasoline and diesel power vehicles, as well as electric and hybrid electric vehicles, feature battery storage for purposes such as powering electric motors, electronics and other vehicle subsystems. Vehicle battery systems may be charged using power sources such as charging stations, other electric vehicle battery systems and/or an electrical grid. Typically, during charging processes, charging currents are limited to protect battery health. It is desirable to provide a device or system that can control charging processes to maximize charging current and minimize charging time while protecting battery components and preserving battery life.

### SUMMARY

In one exemplary embodiment, a system for control of a battery system includes a processor electrically connected to the battery system. The processor is configured to perform, in real time during a charging process, acquiring a set of charging parameter measurements, the charging parameter measurements including a voltage, a current applied to the battery system during the charging process and a temperature of the battery system, and estimating a dynamic performance variable in real time, the dynamic performance variable related to an electrochemical phenomenon occurring within the battery system during the charging process. The processor is also configured to perform, in real time during the charging process, determining a charging limit based on the dynamic performance variable and a model of the battery system, predicting a future state of the battery system, generating a target current profile based on the future state and the charging limit, the target current profile configured to maintain the dynamic performance variable within the charging limit, and controlling the current applied to the battery system based on the target current profile.

In addition to one or more of the features described herein, the model is a mathematical model configured to simulate electrochemical processes in the battery system.

In addition to one or more of the features described herein, generating the target current profile and controlling the current is performed by a model predictive controller (MPC).

In addition to one or more of the features described herein, the dynamic performance variable is selected from at least one of an electrolyte ion concentration at an anode side of a battery cell, an anode potential, a decay rate of electrolyte anode concentration, and a capacity loss.

In addition to one or more of the features described herein, the charging limit includes a performance variable limit being at least one of: a capacity loss limit, an anode potential limit, and a limit to the electrolyte ion concentration at the anode side of the battery cell.

In addition to one or more of the features described herein, predicting the future state and generating the target current profile is performed based on the model and a cost function configured to minimize a cost associated with charge time.

In addition to one or more of the features described herein, the charging limit is determined based on minimizing a state of charge (SOC) tracking error.

In addition to one or more of the features described herein, the processor is configured to receive a pre-specified current profile, and update the pre-specified current profile with the target current profile.

In addition to one or more of the features described herein, the dynamic performance variable includes an aging parameter.

In addition to one or more of the features described herein, the processor is configured to periodically update the model to reflect effects of aging of the battery system, wherein the periodic update is performed locally or at a remote location.

In another exemplary embodiment, a method of controlling a battery system includes acquiring, by a processor electrically connected to the battery system in real time during a charging process, a set of charging parameter measurements, the charging parameter measurements including a voltage, a current applied to the battery system during the charging process and a temperature of the battery system. The method also includes estimating a dynamic performance variable in real time, the dynamic performance variable related to an electrochemical phenomenon occurring within the battery system during the charging process, determining a charging limit based on the dynamic performance variable and a model of the battery system, and predicting a future state of the battery system, and generating a target current profile based on the future state and the charging limit, the target current profile configured to maintain the dynamic performance variable within the charging limit. The method further includes controlling the current applied to the battery system based on the target current profile.

In addition to one or more of the features described herein, the model is a mathematical model configured to simulate electrochemical processes in the battery system.

In addition to one or more of the features described herein, the dynamic performance variable is selected from at least one of an electrolyte ion concentration at an anode side of a battery cell, an anode potential, a decay rate of electrolyte anode concentration, and a capacity loss.

In addition to one or more of the features described herein, the charging limit includes a performance variable limit being at least one of: a capacity loss limit, an anode potential limit, and a limit to the electrolyte ion concentration at the anode side of the battery cell.

In addition to one or more of the features described herein, predicting the future state and generating the target current profile is performed based on the model and a cost function configured to minimize a cost associated with charge time.

In addition to one or more of the features described herein, the dynamic performance variable includes an aging parameter, the method further comprising periodically updating the model to reflect effects of aging of the battery system, wherein the periodic update is performed locally or at a remote location.

In yet another exemplary embodiment, a vehicle system includes a memory having computer readable instructions, and a processing device for executing the computer readable instructions, the computer readable instructions controlling the processing device to perform a method. The method includes acquiring, by a processor electrically connected to the battery system in real time during a charging process, a set of charging parameter measurements, the charging parameter measurements including a voltage, a current applied to the battery system during the charging process and a temperature of the battery system. The method also includes, estimating a dynamic performance variable in real time, the dynamic performance variable related to an electrochemical phenomenon occurring within the battery system during the charging process, determining a charging limit based on the dynamic performance variable and a model of the battery system, predicting a future state of the battery system, and generating a target current profile based on the future state and the charging limit, the target current profile configured to maintain the dynamic performance variable within the charging limit. The method further includes controlling the current applied to the battery system based on the target current profile.

In addition to one or more of the features described herein, the dynamic performance variable is selected from at least one of an electrolyte ion concentration at an anode side of a battery cell, an anode potential, a decay rate of electrolyte anode concentration, and a capacity loss, and the charging limit includes a performance variable limit being at least one of: a capacity loss limit, an anode potential limit, and a limit to the electrolyte ion concentration at the anode side of the battery cell.

In addition to one or more of the features described herein, predicting the future state and generating the target current profile is performed based on the model and a cost function configured to minimize a cost associated with charge time.

In addition to one or more of the features described herein, the dynamic performance variable includes an aging parameter, the method further including periodically updating the model to reflect effects of aging of the battery system, wherein the periodic update is performed locally or at a remote location.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a top view of a motor vehicle including a battery assembly or system and a battery charging system, in accordance with an exemplary embodiment;

FIG. 2 depicts components of a battery charging control system, in accordance with an exemplary embodiment;

FIG. 3 is a flow diagram depicting aspects of a method of charging a battery assembly or system, in accordance with an exemplary embodiment;

FIGS. 4A-4D depict examples of charging parameters and performance variables associated with a charging process performed in accordance with the method of FIG. 3;

FIG. 5 schematically depicts aspects of a method of charging a battery system or assembly, in accordance with an exemplary embodiment; and

FIG. 6 depicts a computer system in accordance with an exemplary embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features.

In accordance with an exemplary embodiment, methods, devices and systems are provided for controlling charging of a battery system, such as an electric vehicle or hybrid vehicle battery system. The embodiments may be applicable to various charging processes, such as conventional charging and DC fast charging (DCFC). For example, the embodiments can be employed in DCFC processes to prevent degradation of battery health due to high currents and factors such as lithium plating.

An embodiment of a method includes receiving measurements of charging parameters during a vehicle battery charging process, and calculating one or more dynamic variables that are based on electrochemical phenomena that occur during the charging process. Examples of dynamic variables include liquid phase Lithium ion concentration of electrolyte around an anode current collector, anode potential, lithium plating or related variables (e.g., anode potential drop) and others. The dynamic variables are estimated based on the charging parameter measurements and electrochemical properties of the battery system. At least one dynamic variable may be estimated using a mathematical model of the battery system (“battery model”), such as a pseudo-two dimensional model or other physics-based model.

The dynamic variables and charging parameter measurements may be input to the model to generate predictions and maximize the charging current to be applied, subject to one or more charging constraints or limits. The constraints and limits are used to control an amount of current being applied to the battery system during charging (e.g., via closed loop control), so that costs such as charge time are minimized or reduced without compromising battery health. The method may be performed continuously or periodically (e.g., at successive time steps) so that the limits are calculated and applied dynamically as charging conditions change.

It is noted that embodiments are not limited to the specific models described herein, as any suitable models or simulations that capture electrochemical phenomena may be used. The embodiments are described in conjunction with examples in which the same battery model is used for dynamic variable estimation and prediction/optimization. However, different models may be used for estimation and prediction/optimization as desired.

Embodiments described herein present numerous advantages and technical effects. The embodiments provide for effective control of battery charging parameters, so that charging time can be reduced or minimized while simultaneously maintaining charging current within prescribed limits. Current practices typically calculate current limits considering various battery health factors; however, such practices can be overly conservative, resulting in sub-optimal charging times. The embodiments described herein are able to relax current limits based on predictions, so that charging times can be improved without negative effects.

The embodiments are not limited to use with any specific vehicle and may be applicable to various contexts. For example, embodiments may be used with automobiles, trucks, aircraft, construction equipment, farm equipment, automated factory equipment and/or any other device or system for which additional thermal control may be desired to facilitate a device or system's existing thermal control capabilities or features.

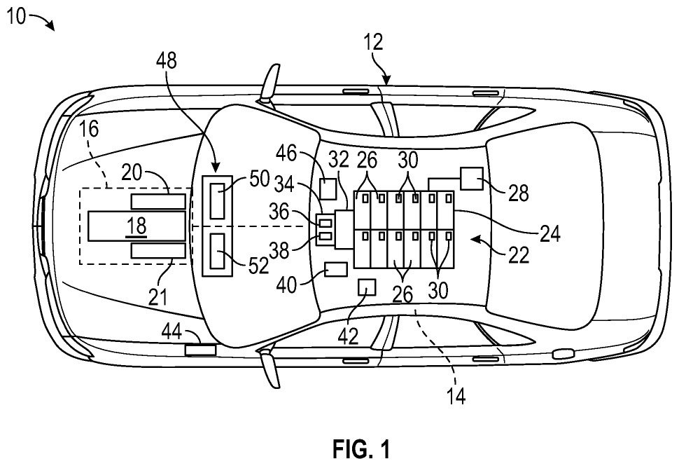

FIG. 1 shows an embodiment of a motor vehicle 10, which includes a vehicle body 12 defining, at least in part, an occupant compartment 14. The vehicle body 12 also supports various vehicle subsystems including a propulsion system 16, and other subsystems to support functions of the propulsion system 16 and other vehicle components, such as a braking subsystem, a suspension system, a steering subsystem, a fuel injection subsystem, an exhaust subsystem and others.

The vehicle 10 may be a combustion engine vehicle, an electrically powered vehicle (EV) or a hybrid vehicle. In an embodiment, the vehicle 10 is a hybrid vehicle that includes a combustion engine assembly 18 and at least one electric motor assembly. For example, the propulsion system 16 includes a first electric motor 20 and a second electric motor 21. The motors 20 and 21 may be configured to drive wheels on opposing sides of the vehicle 10. Any number of motors positioned at various locations may be used.

The vehicle 10 includes a battery system 22, which may be electrically connected to the motors 20 and 21 and/or other components, such as vehicle electronics. The battery system 22 may be configured as a rechargeable energy storage system (RESS).

In an embodiment, the battery system 22 includes a battery assembly such as a high voltage battery pack 24 having a plurality of battery modules 26. Each of the battery modules 26 includes a number of individual cells (not shown). The battery system 22 may also include a monitoring unit 28 (e.g., RESS controller) configured to receive measurements from sensors 30. Each sensor 30 may be an assembly or system having one or more sensors for measuring various battery and environmental parameters, such as temperature, current and voltages. The monitoring unit 28 includes components such as a processor, memory, an interface, a bus and/or other suitable components.

The battery system 22 is electrically connected to a direct current (DC)-DC converter module 32 and an inverter module 34. The inverter module 34 (e.g., a traction power inversion unit or TPIM) converts direct current (DC) power from the battery assembly to three-phase alternating current (AC) power to drive the motors. In an embodiment, the inverter module 34 includes a first inverter 36 connected to the motor 20, and a second inverter 38 connected to the motor 21.

The battery system 22 may also be connected to other vehicle components or systems. For example, the battery system 22 is connected to an auxiliary power module (APM) 40, which controls power output to components such as a heating system. The APM 40 can be used to supply power from the battery system 22 for heating the occupant compartment 14.

The vehicle 10 may include a charging system that can be used to charge the battery pack 24 and/or used for supplying power from the battery pack 24 to charge another energy storage system (e.g., vehicle-to-vehicle charging). The charging system includes an onboard charging module (OBCM) 42 that is electrically connected to a charge port 44.

In an embodiment, the vehicle 10 includes a charging control system configured to control charging parameters based on electrochemical phenomena. As discussed further herein, the charging control system calculates values of one or more dynamic variables corresponding to such phenomena, and controls charging current or applied current based on limits calculated using the dynamic variables and a battery model. The charging control system includes a processing device or processor, which may be any suitable processor, such as the monitoring unit (e.g., RESS controller) 28, the OBCM 42 or a dedicated controller 46.

The vehicle 10 also includes a computer system 48 that includes one or more processing devices 50 and a user interface 52. The various processing devices and units may communicate with one another via a communication device or system, such as a controller area network (CAN) or transmission control protocol (TCP) bus.

The charging control system utilizes a set (i.e., one or more) of defined performance variables that are estimated in real time and used in real time to adapt current requests to maintain applied current within one or more limits, to improve or maximize charging time while avoiding negative effects (e.g., lithium plating). Values of the one or more performance variables are estimated using a battery model to generate estimates of values of these variables. The performance variables are analyzed/input to the battery model, and an estimator determines a charging current that reduces or minimize costs (e.g., charging duration) subject to limits and constraints within the model. The determined charging current may be represented as a “target current profile”.

Examples of performance variables include dynamics related to electrolyte liquid-phase lithium concentration (cₑ) at an anode current collector (e.g., rate of decay of cₑ at an anode), anode and cathode solid-phase lithium concentrations, anode potential (Vₙ), cathode potential and dynamics related to electrolyte and electrode concentrations and anode potential. The liquid phase lithium concentration of electrolyte at the anode is referred to herein as “anode electrolyte concentration.”

In an embodiment, the performance variables are generated for lithium-ion battery cells, but are not so limited. For example, the model and performance variables can be adapted for various other types of battery chemistries.

Aspects of the methods described herein can be performed using a local controller in a vehicle (e.g., the monitoring unit 28 or other processor of the vehicle's battery management system (BMS)), a remote processing device, or a combination thereof). For example, some functions may be performed by a vehicle processor, and other functions may be performed in a cloud computing system or other network (e.g., via vehicle-to-cloud communication).

The charging control system is configured to control current during charging by limiting the current (or C-rate) based on the one or more performance variables using a mathematical model of a battery cell. The mathematical model simulates electrochemical and physical processes that occur when a battery cell is being charged and/or discharged. In an embodiment, the model is a physics-based model of a lithium-ion battery cell (or other chemistry). Examples of such models include microscale models, pseudo three-dimensional models (P3Ds), pseudo two-dimensional models (P2D), single particle models (SPMs) and SPMe (SPM with electrolyte).

In an embodiment, the model is a P2D model, which is also referred to as a Doyle-Fuller-Newman (DFN) model or Newman model. The P2D model describes transport of lithium ions, cell thermodynamics and kinetics within a lithium ion battery cell.

The P2D model simulates electrochemical processes based on a simulation of a lithium-ion cell. The cell includes a porous anode and cathode, which are made from solid active materials that can store lithium intercalated in the solid material. The anode is connected to an anode current collector and the cathode is connected to a cathode current collector. A separator is disposed between the anode and the cathode, and allows the passage of ions but not electrons. The porous electrodes and the separator are soaked in an electrolyte, which allows the transport of ions.

During discharge, lithium stored in the anode is released as ions in the electrolyte. Driven by diffusion (concentration gradient) and migration (electric potential gradient), lithium ions travel through the separator to the cathode where they are inserted in the lattice of the cathode active material.

Simultaneously, electrons travel from the anode to the cathode through an external circuit. This process is reversed during battery charging.

The P2D model simulates a battery cell, and accounts for a number of variables. The variables are related to lithium ion concentration and transport, temperature, electrical potential and other phenomena. The variables also include one or more selected performance variables. Using the battery model, the charging control system estimates future states of the battery cell (i.e., battery cell state at a time step that succeeds a current or instant time step), including predicted values of the performance variables. The predicted values of the performance variables are used to control the applied current so that the predicted values stay within performance variable limits. Control of the applied current may also be subject to other limits (e.g., maximum current and voltage).

The following equations represent an example of a model that can be used for estimation of dynamic variables and/or optimization/prediction. In this example, the model is a simplified version of a full-order P2D model. Dependent variables in the model include lithium ion concentration in the electrolyte (i.e., electrolyte concentration cₑ), average lithium ion concentration in the solid phase in the electrodes (i.e. average concentration cₐ), and surface lithium ion concentration in the solid phase in the electrodes (i.e., surface concentration cₛ). The concentrations are represented using the subscript i to indicate the positive side of the battery (i=p) and the negative side (i=n). For example, cₑ at the positive side is denoted c_{e,p}, and cₑ at the negative side is denoted c_{e,n}.

Charge dynamics in the cell can be described using sets of ordinary differential equations (ODEs). For example, the time derivatives of c_{a,i} and c_{s,i} and c_{e,i} can be calculated using a set of ODEs as follows:

[ċ_{a,i},ċ_{s,i}]=ODE(c_{a,i},c_{s,i},T,I,p),

[ċ_{e,i}]=ODE(c_{e,i},I,p)

where T is temperature of the cell, I is current and p is a static parameter (or set of static parameters). The time derivative of Tis a function of T, I and p.

In addition, model parameters can be adjusted or configured to reflect effects of aging during long-term use of a battery system. For example, an aging parameter such as capacity loss (qₗₒₛₛ) is incorporated into the model so that battery behavior over a life cycle of a battery system is accounted for. Aging parameters can be updated locally within a vehicle or remotely (e.g., transmitting charging parameter measurements and charg control information to a cloud network, and receiving over the air updates). For example, the model can be periodically updated (e.g., after each completed charging process or after a selected number of completed charging processes), either locally or over the cloud.

Using the model, various parameters can be calculated and/or predicted. The following equations represent examples of calculations of state of charge (SOC), capacity loss (qₗₒₛₛ), difference in electrochemical potential between the anode and the cathode (ΔΦ) over the electrolyte, and overpotential (ηᵢ):

$$SoC = ( ( \frac{{c}_{a , n}}{{c}_{a , n}^{max}} ) - {θ}_{n}^{min} ) / ( {θ}_{n}^{max} - {θ}_{n}^{min} ) \\ \begin{matrix}{q}_{loss} ( \% ) = {a}_{c} ( . ) exp ( - {E}_{ac} / RT ) . {Ah}^{n} & p = p ( {q}_{{loss}^{+}} . )\end{matrix} \\ ΔΦ = {K}_{eff} ( p ) . {C}_{rate} + {K}_{e} T [ ln ( \frac{{c}_{e , p}}{{c}_{e , n}} ) ] \\ {η}_{i} = \frac{2 TR}{F} . a sinh ( f ( I , {c}_{e , i} , {c}_{s , i} , p ) )$$

In the above equations, c_{a,n} is solid phase concentration at the anode, c_{a,n}^{max}: is a maximum solid phase concentration at the anode, θₙ^{min} is a minimum state of charge at the anode, and θₙ^{max} is a maximum state of charge at the anode. a_{c} is a fitting factor, E_{ac} is activation energy, R is a constant, and Ahⁿ is total capacity. K_{eff} is effective electrolyte conductivity, and Cᵣₐₜₑ is the C-rate.

The open circuit voltage (V_{oc}) of the cell, and the cell voltage (V_{cell}), can be calculated as follows:

$${V}_{oc} = {OCP}_{p} ( {c}_{a , p} , T ) - {OCP}_{n} ( {c}_{a , n} , T ) \\ {V}_{cell} = {V}_{oc} + ΔΦ - {η}_{p} - {η}_{n}$$

where OCPₚ is the open circuit potential at the cathode, OCPₙ is the open circuit potential at the anode, overpotential np is the overpotential at the cathode, and ηₙ is the overpotential at the anode.

As noted above, the charging control system calculates one or more performance variables based on measurements of charging parameters during a charging process.

In an embodiment, the performance variables include electrolyte concentration at an anode current collector (cₑ). During charging, the cₑ at the anode decays from an initial value to a value that decreases within increased C-rate. “C-rate” is defined as a rate at which a battery is discharged relative to a maximum capacity of the battery, and may be a measure of charging current normalized by capacity. A limiting factor of the C-rate is lithium depletion (or electrolyte depletion), which occurs when the concentration cₑ at the anode is close to zero.

For example, a performance variable is a decay rate of the anode electrolyte concentration (i.e., concentration of liquid-phase lithium ions in the separator anode-side). The decay rate is a rate at which the concentration decreases over time, denoted as dcₑ/dt. The decay rate can be calculated according to a rate at which the concentration converts to steady state, based on the following equation:

$$τ \frac{{dc}_{e}}{dt} = {c}_{e} - {c}_{e . ss}$$

where ce is electrolyte concentration at the anode, c_{e,ss} is the steady state concentration. c_{e,ss} is a function of C-rate. τ is a time constant that describes the rate of drop in concentration, which can be a function of C-rate and temperature T.

Anode potential Vₙ (and/or parameters related to anode potential) is another performance variable that can be used for control of charging. The anode potential Vₙ depends on open circuit potential at the anode and overpotential as follows:

$${V}_{n} = {OCP}_{n} ( {c}_{a , n} , T ) + {η}_{i} .$$

At high C-rates, the anode potential Vₙ decreases as SOC increases, and the rate at which the anode potential decreases is more pronounced at low temperatures. If the anode potential drops to zero or negative, lithium plating can occur. Lithium plating is detrimental, as this phenomenon can result in rapid capacity loss and short circuits. Accordingly, by monitoring anode potential dynamics and applying appropriate limits to the charging rate, lithium plating can be avoided while minimizing charge time.

The example of the battery model describes the battery system according to the following equations, where x is a state vector representing a model state (system state). Charging parameter measurements are represented as state vector y. The state vectors may be represented by:

\dot{x}=F(x,u,p)

y=G(x,u,p),

where u is an input to the model (e.g., current I). F and G are functions of the input (u=I), the state vector x and static variables p.

A system state (e.g., system state at an instant time step) is represented by a first set of parameters, and the model output is represented by a second set of parameters, examples of which include:

x=[c_{a,n},c_{a,p},c_{s,n},c_{s,p},c_{e,n},c_{e,p},T,qₗₒₛₛ]; and

y=[V_{ceil},T].

A Kalman filter or other suitable algorithm may be used in conjunction with the model to estimate values of performance parameters, such as values of Vₙ. In an embodiment, the algorithm is an extended Kalman filter (EKF). The EKF estimates a state of the battery system at a given time step based on battery charging parameter inputs and measurements. The EKF estimates the continuous-time state of the battery system based on the input model outputs and initial conditions. The estimated state is represented as a continuous-time state \dot{\hat{x}} as follows:

\dot{\hat{x}}=F(\hat{x},u,p)+K·[y−G(\hat{x},u,p)], where K is the Kalman gain. The Kalman gain can be calculated according to the following equations:

$$\dot{\hat{x}} = F ( \hat{x} , u , p ) + K \cdot [ y - G ( \hat{x} , u , p ) ] \\ \dot{P} = FP + {PF}^{′} - KGP + Q \\ F = \partial F / \partial x \\ G = \partial G / \partial x \\ K = {PG}^{′} {R}^{- 1} ,$$

where \hat{x} is the estimated state, P is a predicted covariance estimate, F is a transition matrix from the system state, F′ is the transposed transition matrix, G is a matrix of measurements, and Q is covariance.

In addition to using the model for estimating anode potential and/or other performance variables, the model is used to predict a future state of the battery system. In an embodiment, the prediction is performed using a prediction algorithm such as a Kalman filter. For example, the EKF discussed above is used to predict future system states and determine a current to be applied (also referred to as a “target current”) to the battery system during charging. The value of the target current is maximized using the model and prediction while maintaining the charging process within design limits, performance parameter limits and other limits imposed by the model.

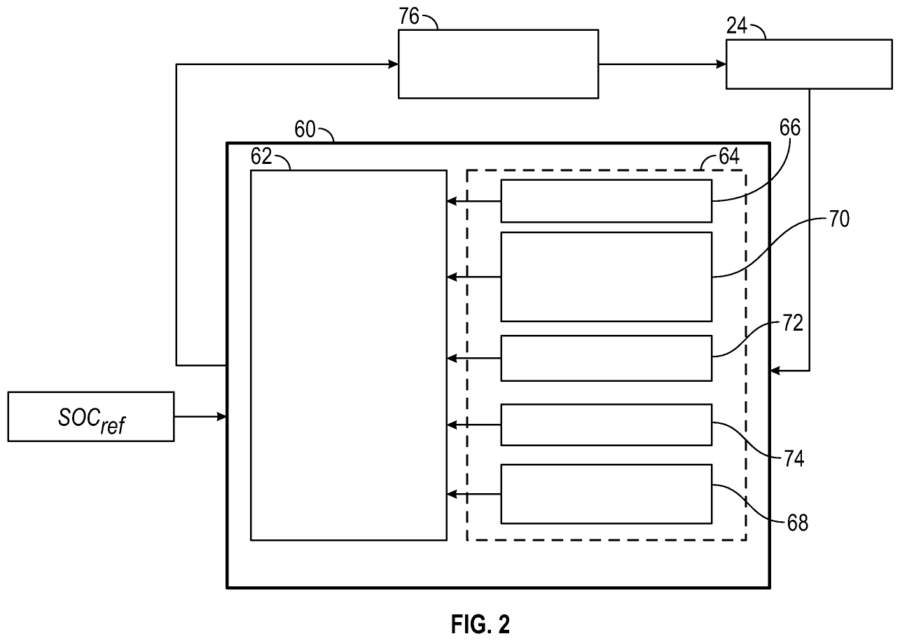

FIG. 2 depicts an embodiment of a charging control system 60. The charging control system 60 includes a first layer 62 (Layer-1) and a second layer 64 (Layer-2). The layers may be individual processors in coordination or a single processor.

As shown, the charging control system 60 is configured to receive charging parameter measurements (e.g., battery voltage V_{batt}, battery current I_{batt} and temperature T_{batt}) in real time, and input the charging parameter measurements to the second layer 64. The second layer 64 uses charging parameter measurements to estimate performance variables (and/or other variables related to battery behavior). The first layer 62 calculates an optimal charge current using the performance variables and predictions, and applies charge current to the battery system 22 or outputs a current request (e.g., target current profile). For example, the first layer and/or the second layer 64 is or includes a model predictive controller (MPC). Functions of the first layer 62 and the second layer 63 may be performed simultaneously or otherwise in parallel.

During charging, various parameters, including performance variables, are calculated by the second layer 64 based on the charging parameter measurements (e.g., V_{batt}, I_{batt} and T_{batt}), and input to the first layer 62. Measurements of V_{batt} may include a voltage measurement of a single cell or group of cells (e.g., a pair of cells or a module 26). For measurements of multiple cells and/or multiple modules, a voltage value can be derived by combining measurements (e.g., mean cell voltage) or providing a representative measurement (e.g., a cell determined to have the lowest state of health).

Examples of calculated parameters include charge time 66 and various pre-selected limits 68 (e.g., limits from another calibration, limits due to battery design, etc.). Performance parameters include, for example, electrolyte ion concentration 70 at the anode, anode potential 72, lithium plating boundary 74 and/or other performance variables (e.g., decay rate, overpotential, capacity loss, etc.).

The first layer 62 may be an optimizer that receives the calculated parameters, performance variables and a SOC reference (SOC_{ref}), which may be a set point or profile. The optimizer inputs these parameters and variables to the model to predict future states of the battery system and determine an optimal target current to be applied to the battery system. For example, the optimizer outputs a charging current request 76 according to the optimal target current to apply charging current to the battery pack 24. The target current is a maximum current (or C-rate) that can be applied (and corresponding minimum charge time), while adhering to limits of performance parameters.

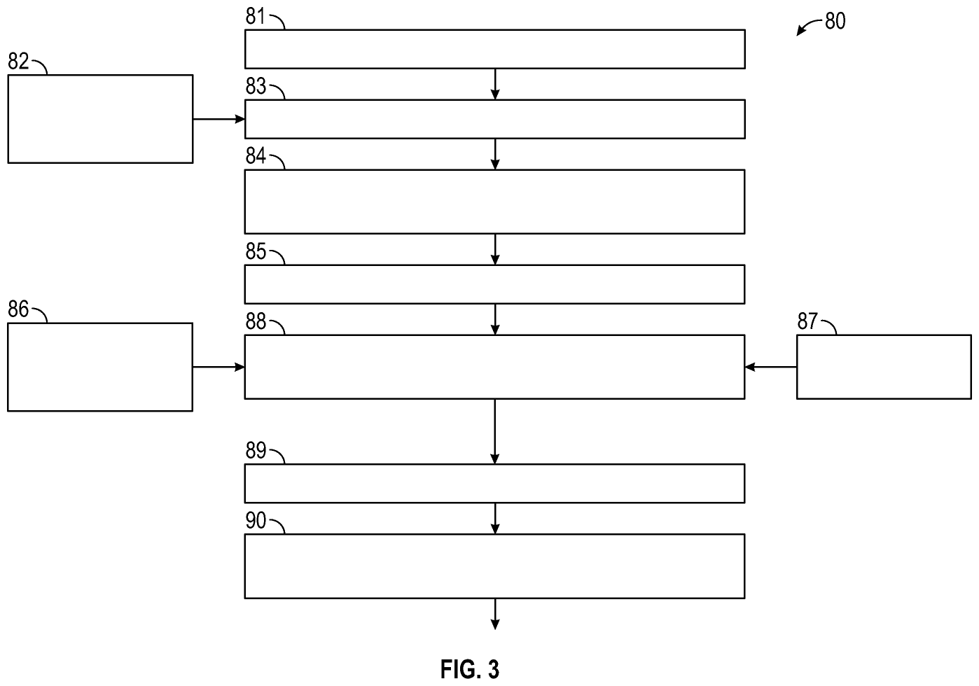

FIG. 3 illustrates embodiments of a method 80 of controlling charging of a battery system. The battery system may be part of a vehicle (e.g., as a HV battery pack or packs) or any other suitable battery system. Aspects of the method 80 may be performed by a processing device or system, such as the OBCM 42 and/or controller 46. In addition, the method 80 is described in conjunction with the vehicle 10 and components thereof, but is not so limited, as the method 80 may be performed in conjunction with any suitable vehicle or battery assembly.

The method 80 includes a number of steps or stages represented by blocks 81-90. The method 80 is not limited to the number or order of steps therein, as some steps represented by blocks 81-90 may be performed in a different order than that described below, or fewer than all of the steps may be performed.

At block 81, a charging process is initiated by connecting the charge port 44 to a power source, such as a DC fast charging (DCFC) charging station. For example, the charge port 44 is connected to a charging station, another vehicle (for vehicle-to-vehicle or V2V charging), a power outlet connected to an electric grid (for vehicle-to-grid charging) or other power source.

The processing device acquires measurements of initial battery parameters (i.e., parameters prior to commencing charging). Examples of such measurements include cell voltage, current, temperature, state of charge and others.

At block 82, the processing device receives an indication as to whether conditions are enabled to permit charging. For example, the processing device receives an indication that a charging mode (e.g., DCFC charging mode) is enabled.

At block 83, initial conditions of the model are determined, which correspond to conditions of the battery system at an onset of the charging process or at a given time step. The initial conditions include initial values of the set of the model state x, and are denoted as x₀. The initial conditions also include an initial values of charging parameter measurements y (denoted as y₀), and an initial current (I₀ or u₀). The initial conditions of the model can this be represented as (x₀,u₀,y₀).

It is noted that the steps or stages represented by blocks 84-90 of the method 80 may be performed repeatedly during charging to provide real time charging limits and adjust the charging limits in real time as conditions change. In this way, charging limits (and corresponding applied currents) are repeatedly or continuously adjusted or updated as needed. As such, a pre-selected charging profile is not required, as charging profiles are determined and updated in real time during the charging process.

However, the method 80 may include receiving a pre-specified charge profile or current profile. The pre-specified profile may be generated based on a baseline calibration.

For example, the steps described at blocks 84-90 are performed at a specific time step. The steps are repeated as desired for one or more subsequent time steps.

At block 84, one or more performance variables are calculated in real time. In an embodiment, an estimator calculates one or more dynamic performance variables from a model, such as the exemplary model discussed herein, and the charging parameter measurements. The estimates can be considered “virtual measurements” which are not directly measured, but rather indirectly estimated from the model. For example, a local copy of the model is used to estimate the performance variable, which may be a copy of an embedded model (e.g., stored in a vehicle system) or a model stored in a cloud network or other remote location.

In an embodiment, an EKF or other estimation algorithm is used to estimate values of the one or more performance variables. For example, the EKF estimation discussed above is performed in conjunction with the exemplary model discussed above.

Examples of performance variables include anode voltage (Vₙ) estimated via the model. It is noted that other estimation techniques may be used, such as data-driven techniques (e.g., neural network) or techniques that combine data-driven and model based estimations.

Optionally, at block 85, a baseline calibration (I_{baseline}) is used to initialize the charging process and provide limits to an initial applied current. The baseline calibration can refer to a pre-specified profile (I_{baseline}), which can be generated from the cell voltage, state-of charge, temperature and/or other parameters during charging.

At block 86, various parameter limits, such as desired charge time, horizon lengths, and other constraints are input to the processing device (e.g., to the optimizer of layer 62). Such limits include design limits related to the performance variables (performance variable limits). Examples of performance variable limits include a capacity loss limit, an anode potential limit, and a limit to an electrolyte concentration at an anode.

At block 87, the battery cell model is accessed by the processing device for use in prediction. The model may be an embedded model, or a model stored remotely (e.g., in a cloud network) and input to the processing device. For example, the stored battery model is a P2D model.

At block 88, the processing device runs the optimizer at layer 62 to minimize costs (e.g., charge time, etc.) subject to limits defined by the model. The optimizer, in essence, can refer to a constrained optimization routine such as quadratic programming (QP) within a model predictive controller (MPC). The processing device predicts future states and determines a charge current limit that maintains the performance variables within prescribed performance variable limits. For example, a charge current limit is calculated that minimizes a SOC tracking error (error between the battery system SOC and reference SOC) using the model. In another example, age-related variables such as capacity loss (qₗₒₛₛ) are minimized.

Based on the prediction and optimization, an optimized target current is determined. The target current may be a profile that specifies current level as a function of time or SOC, such that the SOC is increased as much as possible (minimize cost associated with charge time) while ensuring that performance variables and other parameters stay within prescribed limits (e.g., anode voltage stays above zero or other threshold to avoid lithium plating.)

At block 89, the baseline calibration is optionally used to adjust the charge current limit and target current profile. At block 90, the charging current is applied to the battery system at the given time step according to the target current profile. For example, a current request specifying a target current I_{MPC} is used to apply the charge current.

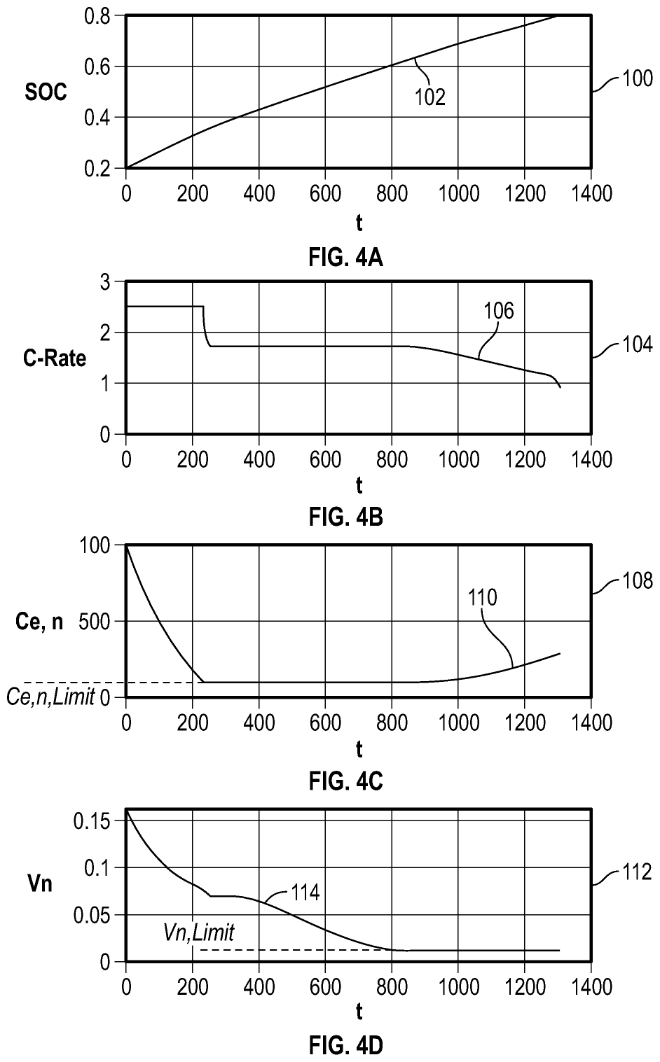

An example of real time charging control is discussed with reference to FIGS. 4A-4D. A charge current limit is calculated at each step during a charging process (according to the method 80) in order to maximize the applied current while minimizing charge time and maintaining the battery system to within limits calculated using the model (including performance variable limits).

In this example, a prediction algorithm is used to predict the battery system state such that the a tracking error J (difference between SOC at the time step and the reference SOC) is minimized. The tracking error can be represented by:

J=Σₖ₌₁ⁿ(SOC−SOC_{ref})²

where SOC_{ref} is the reference SOC, k is a present time step value of SOC, and n is a number of successive time steps for which the tracking error is minimized.

The prediction algorithm is used at each time step to predict a state of the battery system using the battery model (constrained optimization to minimize costs subject to constraints and limits). A charge current limit is calculated that minimizes the tracking error while maintaining variables within limits. The limits include pre-selected maximum voltage (V_{cell}), maximum SOC, maximum current (Iₘₐₓ), and maximum temperature Tₘₐₓ. The limits also include limits to the performance variables, such as a capacity loss limit (q_{loss,max}), an electrolyte concentration limit (c_{e,n,limit}) and an anode potential limit (V_{n,limit}).

FIG. 4A shows a graph 100 of SOC as a function of time, depicting a SOC curve 102. FIG. 4B shows a graph 104 of the C-rate (applied current) as a function of time. A C-rate curve 106 shows how the current limit as adjusted over time using minimization of the tracking error are discussed herein.

FIG. 4C shows a graph 108 of electrolyte concentration at the anode as a function of time, and a ce curve 110. As can be seen, during the charging process, the ce concentration at the anode did not fall below the limit (c_{e,n,limit}).

FIG. 4D shows a graph 112 of anode potential as a function of time, and an anode potential curve 114. As can be seen, during the charging process, the anode potential did not fall below the limit (V_{n,limit}).

Although the modelling, prediction and variable calculations are described as a function of time t, embodiments are not so limited. For example, calculations can be performed as a function of SOC, as both SOC and time increase monotonically during charging. In this example, model variables and charging parameters are converted so that SOC is the independent variable using the following:

$$\frac{dx ( t )}{dt} = \frac{dx ( SoC )}{d ( SoC )} . \frac{d ( SoC )}{dt} , where \\ \frac{dx ( SoC )}{d ( SoC )} = \frac{f ( x , u )}{K . I} .$$

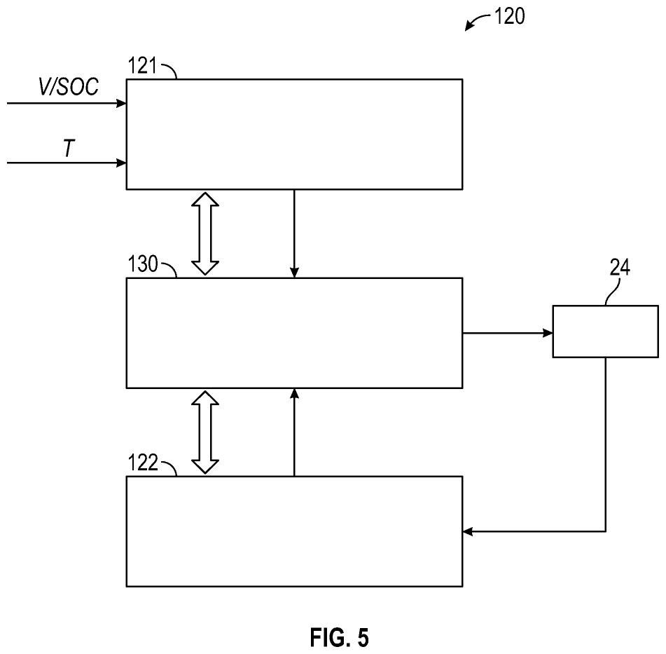

In an embodiment, the charging control system is configured to generate a baseline calibration that can be used in conjunction with generation of current limits or charging limits based on performance variables. FIG. 5 schematically depicts an embodiment of a method 120 of controlling battery charging. The method 120 includes initially generating a baseline calibration I_{baseline} that prescribes an initial current profile as a function of SOC (represented by block 121), cell voltage, temperature and other parameters. The baseline calibration is used in conjunction with predictive control as described herein (represented by block 122) to generate and output a current request to the battery system (e.g., battery pack 24), for example, by inputting I_{baseline} as an initial value (e.g., at block 85 of the method 80).

In an embodiment, the baseline calibration I_{baseline} is continuously or periodically updated (e.g., each time step) using a machine learning process or other process. For example, a learning agent including a neural network based machine learning algorithm periodically updates the baseline calibration.

For example, the baseline calibration I_{baseline} is calculated and updated based on the following equation:

$${I}_{baseline} ( SoC ) ← α {I}_{baseline} ( SoC ) + ( 1 - α ) {I}_{MPC} ( SoC ) ,$$

where I_{MPC} is a current request generated using predictive control according to the method 80. I_{MPC} and I_{baseline} can be a function of SOC as shown above, or a function of time or other independent variables like cell voltage, temperature and so on. The baseline can be combined with predictive control by any suitable processing device, such as the OBCM, a processor in the battery system (e.g., a battery management controller), or an add-on processing component 130 as shown in FIG. 5.

An additional calibration can be applied to limit variations in the current request to some percentage or proportion of I_{baseline}. For example, the current request I_{MPC} is adjusted to a minimum of a selected percentage (β) of the baseline calibration I_{baseline} and the current request I_{MPC} as follows:

I_{DCFC}(SoC)=min(βI_{baseline}(SoC),I_{MPC}(SoC)).

For example, referring to FIG. 5, I_{baseline} is generated at block 121 and I_{MPC} is generated and output to the processing component 130. The processing component adjusts I_{MPC} by weighting current values using the baseline calibration and applies the current to the battery system (e.g., as an output current I_{DCFC}).

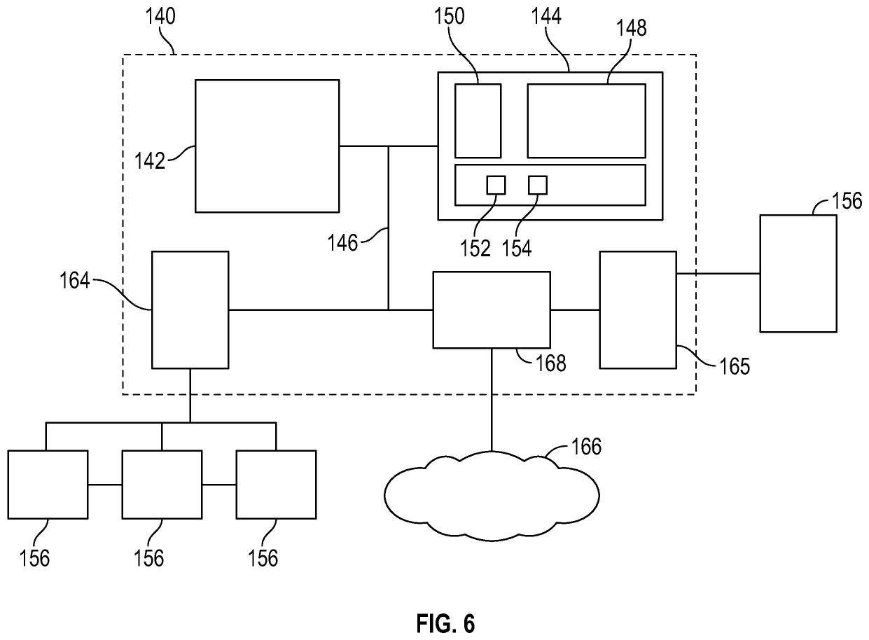

FIG. 6 illustrates aspects of an embodiment of a computer system 140 that can perform various aspects of embodiments described herein. The computer system 140 includes at least one processing device 142, which generally includes one or more processors for performing aspects of image acquisition and analysis methods described herein.

Components of the computer system 140 include the processing device 142 (such as one or more processors or processing units), a memory 144, and a bus 146 that couples various system components including the system memory 144 to the processing device 142. The system memory 144 can be a non-transitory computer-readable medium, and may include a variety of computer system readable media. Such media can be any available media that is accessible by the processing device 142, and includes both volatile and non-volatile media, and removable and non-removable media.

For example, the system memory 144 includes a non-volatile memory 148 such as a hard drive, and may also include a volatile memory 150, such as random access memory (RAM) and/or cache memory. The computer system 140 can further include other removable/non-removable, volatile/non-volatile computer system storage media.

The system memory 144 can include at least one program product having a set (e.g., at least one) of program modules that are configured to carry out functions of the embodiments described herein. For example, the system memory 144 stores various program modules that generally carry out the functions and/or methodologies of embodiments described herein. A module 152 may be included for performing functions related to monitoring a battery system, and a module 154 may be included to perform functions related to controlling charging using predictive control as described herein. The system 140 is not so limited, as other modules may be included. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

The processing device 142 can also communicate with one or more external devices 156 as a keyboard, a pointing device, and/or any devices (e.g., network card, modem, etc.) that enable the processing device 142 to communicate with one or more other computing devices. Communication with various devices can occur via Input/Output (I/O) interfaces 164 and 165.

The processing device 142 may also communicate with one or more networks 166 such as a local area network (LAN), a general wide area network (WAN), a bus network and/or a public network (e.g., the Internet) via a network adapter 168. The network may be a cloud computing network that a vehicle can wirelessly communication with. It should be understood that although not shown, other hardware and/or software components may be used in conjunction with the computer system 40. Examples include, but are not limited to: microcode, device drivers, redundant processing units, external disk drive arrays, RAID systems, and data archival storage systems, etc.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A system for control of a battery system, comprising:
a processor electrically connected to the battery system, the processor configured to perform, in real time during a charging process:
acquiring a set of charging parameter measurements, the charging parameter measurements including a voltage, a current applied to the battery system during the charging process and a temperature of the battery system;
estimating a dynamic performance variable in real time, the dynamic performance variable related to an electrochemical phenomenon occurring within the battery system during the charging process;
determining a charging limit based on the dynamic performance variable and a model of the battery system;
predicting a future state of the battery system, and generating a target current profile based on the future state and the charging limit, the target current profile configured to maintain the dynamic performance variable within the charging limit; and
controlling the current applied to the battery system based on the target current profile.

2. The system of claim 1, wherein the model is a mathematical model configured to simulate electrochemical processes in the battery system.

3. The system of claim 2, wherein generating the target current profile and controlling the current is performed by a model predictive controller (MPC).

4. The system of claim 1, wherein the dynamic performance variable is selected from at least one of an electrolyte ion concentration at an anode side of a battery cell, an anode potential, a decay rate of electrolyte anode concentration, and a capacity loss.

5. The system of claim 4, wherein the charging limit includes a performance variable limit being at least one of: a capacity loss limit, an anode potential limit, and a limit to the electrolyte ion concentration at the anode side of the battery cell.

6. The system of claim 1, wherein predicting the future state and generating the target current profile is performed based on the model and a cost function configured to minimize a cost associated with charge time.

7. The system of claim 6, wherein the charging limit is determined based on minimizing a state of charge (SOC) tracking error.

8. The system of claim 1, wherein the processor is configured to receive a pre-specified current profile, and update the pre-specified current profile with the target current profile.

9. The system of claim 1, wherein the dynamic performance variable includes an aging parameter.

10. The system of claim 9, wherein the processor is configured to periodically update the model to reflect effects of aging of the battery system, wherein the periodic update is performed locally or at a remote location.

11. A method of controlling a battery system, comprising:
acquiring, by a processor electrically connected to the battery system in real time during a charging process, a set of charging parameter measurements, the charging parameter measurements including a voltage, a current applied to the battery system during the charging process and a temperature of the battery system;
estimating a dynamic performance variable in real time, the dynamic performance variable related to an electrochemical phenomenon occurring within the battery system during the charging process;
determining a charging limit based on the dynamic performance variable and a model of the battery system;
predicting a future state of the battery system, and generating a target current profile based on the future state and the charging limit, the target current profile configured to maintain the dynamic performance variable within the charging limit; and
controlling the current applied to the battery system based on the target current profile.

12. The method of claim 11, wherein the model is a mathematical model configured to simulate electrochemical processes in the battery system.

13. The method of claim 11, wherein the dynamic performance variable is selected from at least one of an electrolyte ion concentration at an anode side of a battery cell, an anode potential, a decay rate of electrolyte anode concentration, and a capacity loss.

14. The method of claim 13, wherein the charging limit includes a performance variable limit being at least one of: a capacity loss limit, an anode potential limit, and a limit to the electrolyte ion concentration at the anode side of the battery cell.

15. The method of claim 11, wherein predicting the future state and generating the target current profile is performed based on the model and a cost function configured to minimize a cost associated with charge time.

16. The method of claim 11, wherein the dynamic performance variable includes an aging parameter, the method further comprising periodically updating the model to reflect effects of aging of the battery system, wherein the periodic update is performed locally or at a remote location.

17. A vehicle system comprising:
a memory having computer readable instructions; and
a processing device for executing the computer readable instructions, the computer readable instructions controlling the processing device to perform a method including:
acquiring, by a processor electrically connected to the battery system in real time during a charging process, a set of charging parameter measurements, the charging parameter measurements including a voltage, a current applied to the battery system during the charging process and a temperature of the battery system;
estimating a dynamic performance variable in real time, the dynamic performance variable related to an electrochemical phenomenon occurring within the battery system during the charging process;
determining a charging limit based on the dynamic performance variable and a model of the battery system;
predicting a future state of the battery system, and generating a target current profile based on the future state and the charging limit, the target current profile configured to maintain the dynamic performance variable within the charging limit; and
controlling the current applied to the battery system based on the target current profile.

18. The vehicle system of claim 17, wherein the dynamic performance variable is selected from at least one of an electrolyte ion concentration at an anode side of a battery cell, an anode potential, a decay rate of electrolyte anode concentration, and a capacity loss, and the charging limit includes a performance variable limit being at least one of: a capacity loss limit, an anode potential limit, and a limit to the electrolyte ion concentration at the anode side of the battery cell.

19. The vehicle system of claim 17, wherein predicting the future state and generating the target current profile is performed based on the model and a cost function configured to minimize a cost associated with charge time.

20. The vehicle system of claim 17, wherein the dynamic performance variable includes an aging parameter, the method further including periodically updating the model to reflect effects of aging of the battery system, wherein the periodic update is performed locally or at a remote location.
